(19) United States
(12) Patent Application Publication
(10) Pub. No.: US 2008/0001647 A1
(43) Pub. Date: Jan. 3, 2008

(54) Temperature stabilized integrated circuits

(76) Inventor: George Stennis Moore, Veradale, WA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/478,954

(22) Filed: Jun. 29, 2006

(51) Int. Cl. H01L 35/00

(52) U.S. Cl. 327/512

(57) ABSTRACT

Temperature stabilization of an integrated circuit to reduce effects of data and activity variation. Heat dissipating load structures are integrated onto the die and controlled in response to sensed device characteristics. In a first embodiment, heat dissipating load structures on the device are used to maintain constant device power dissipation. In a second embodiment, the heat dissipating load structures are used in conjunction with on-device temperature sensors to maintain constant device temperature.

### TECHNICAL FIELD

Embodiments in accordance with the invention are related to temperature stabilization of integrated circuit devices.

### BACKGROUND

Complex integrated circuits, particularly mixed signal and high frequency integrated circuits such as analog to digital converters, digital to analog converters, and radio frequency circuits consume electrical power, which results in device heating. This heating in some circuit topologies is dependent on activity and/or data. As an example, data patterns in a high speed converter may affect device operating temperatures. While the integrated circuit substrate and packaging act to even out and dissipate these data and activity dependent effects, temperature variations so caused can affect device calibration premised on operation at a constant or specified temperature.

### BRIEF DESCRIPTION OF THE DRAWINGS

FIG. 1 shows a block diagram of an integrated circuit,

FIG. 2 shows a second diagram of an integrated circuit,

FIG. 3 shows a third diagram of an integrated circuit, and

FIG. 4 shows a fourth diagram of an integrated circuit.

### DETAILED DESCRIPTION OF THE EMBODIMENTS

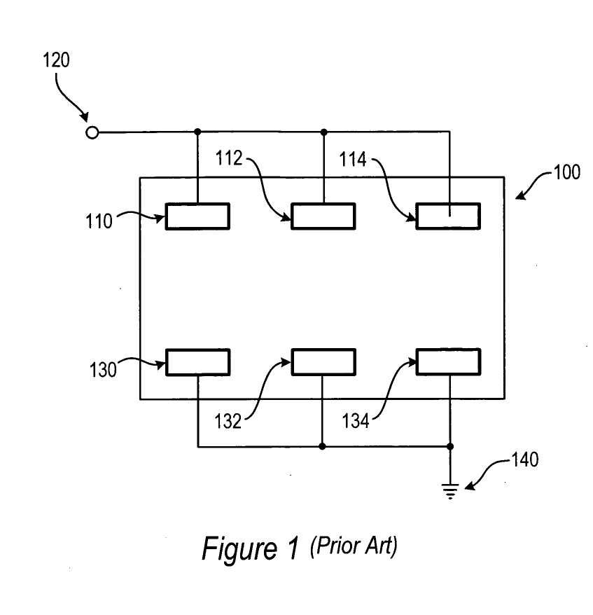

FIG. 1 is a simplified diagram of an integrated circuit showing power connections. Die 100 has multiple bonding pads 110, 112, 114 for supplying power from source 120 through lead wires. Multiple ground bonding pads 130, 132, 134 connect via lead wires to ground 140 completing the electrical circuit. Die 100 is commonly mounted to a substrate or other packaging, not shown, which helps dissipate heat generated by the operation of the circuitry contained in die 100. Target circuitry, such as analog to digital or digital to analog conversion and associated bonding pads, are not shown.

While the present invention is shown with one power supply, it is equally applicable to integrated circuits using multiple power supplies.

In operation of an integrated circuit, particularly in high-speed integrated circuits, electrical power is turned into heat. In many cases, this heating may be signal or data dependent. Such temperature variations affect calibration premised on device operation at a constant or specific temperature.

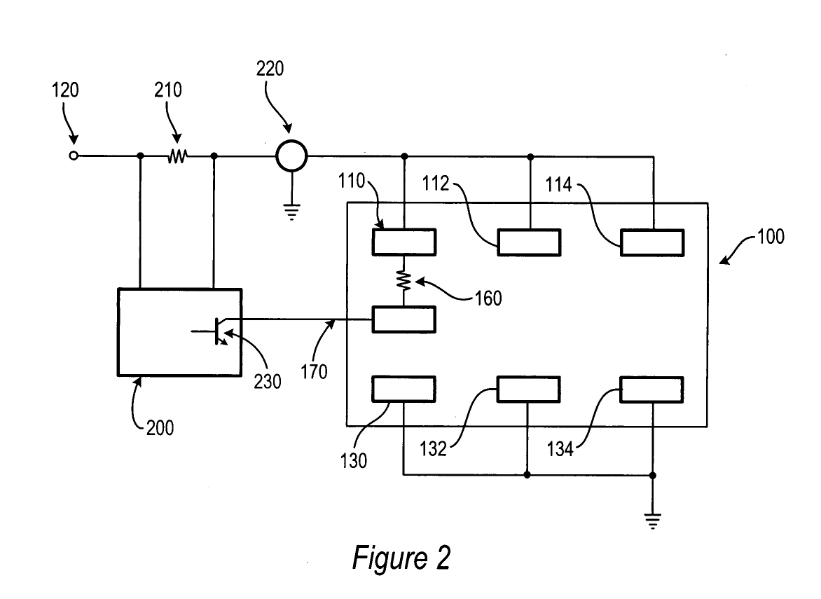

In a first embodiment of the invention as shown in FIG. 2, die 100 is operated in a mode where the power supply current to the die is held constant. Die 100 contains heat generating load element 160 which connects through bonding pad 110 to power supply 220. Power regulator 220 provides a fixed and regulated voltage to die 100 through bonding pads 110, 112, 114, with supply return through pads 130, 132, 134.

Die 100 is operated in a constant-current mode using controller 200 and sense resistor 210. Applying Ohm's law, current flowing through resistor 210 results in a voltage drop across resistor 210. This voltage is sensed by controller 200, which controls 170 the current flowing through load element 160 in such a manner that the voltage drop across sense resistor 210 is held constant. Since regulator 220 provides a fixed voltage to die 100, the product of this fixed voltage and a constant current as maintained by controller 200 holds die 100 at a constant power dissipation level, stabilizing die temperature.

Other methods may also be used to sense the operating current of die 100. A Hall effect sensor may be used to sense current flowing through a supply line or trace. It may be possible to sense current through the operation of regulator 220; as an example, some switching regulator topologies will vary switching frequency as a function of load current. While FIG. 2 shows a single load element 160 on die 100, multiple heat generating load elements 160 may be used to provide a more uniform thermal environment.

Additionally, while transistor 230 controlling 170 current through load 160 is shown as part of controller 200, it may be located on die 100. It may be advantageous to use transistors as heat generating load elements on die 100, or transistor-resistor combinations.

Controller 200 may be an analog control loop, or a digital or mixed analog and digital loop. This functionality may also be substantially embedded on die 100; while active elements such as op amps, logic gates, and such may be easily integrated onto die 100, the circuit topology chosen may require timing components such as resistors and/or capacitors which may be desirable to place off-die and connect through bonding pads. The bandwidth of the control loop must consider thermal time constants of the die and its packaging.

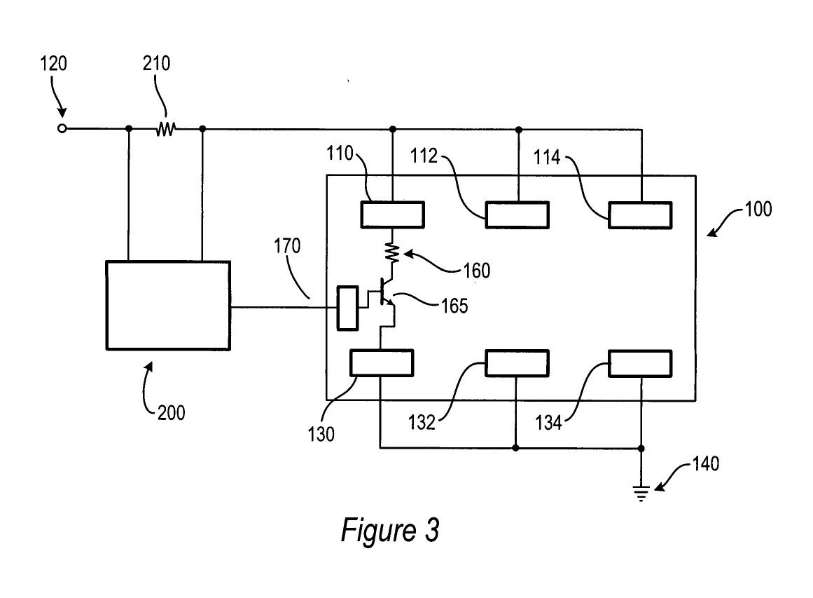

A second embodiment of the present invention is shown in FIG. 3. Load element 160 and transistor 165 are part of die 100 and generate heat when conducting current from supply pad 110 to ground pad 130 under control 170 of controller 200. Sense resistor 210 senses the current flowing through die 100, developing a voltage drop proportional to the current. In operating die 100 in a constant-current mode, controller 200 operates to keep the voltage drop across sense resistor 210 at a constant value.

In the embodiment of FIG. 2, the voltage drop introduced by sense resistor 210 is compensated for by placing sense resistor 210 before voltage regulator 220. In the embodiment of FIG. 3, the voltage drop introduced by sense resistor 210 must be compensated for by recharacterizing the operation of the devices on die 100 at a slightly reduced operating voltage, or by raising the operating voltage supplied to die 100 through sense resistor 110 to compensate for the voltage drop.

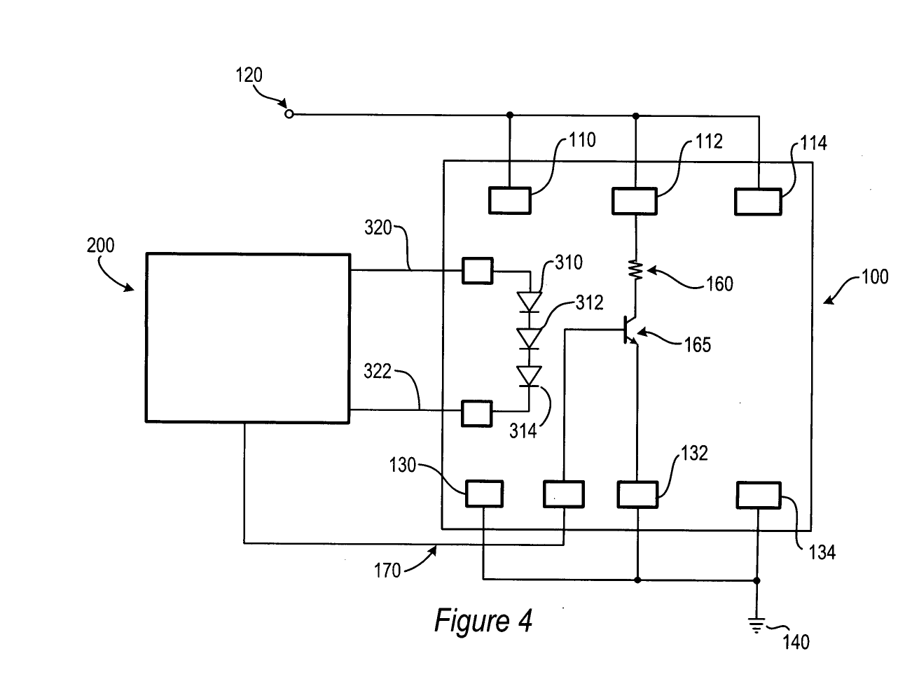

The embodiment of FIG. 3 also allows sense resistor 210 to be integrated into die 100. In such an embodiment, sense resistor 210 may also be used as a source of heat.

Where the embodiments shown in FIGS. 2 and 3 use heat generating load elements in a constant-current operating regime, the embodiment of FIG. 4 senses die temperature and provides that information to controller 200. The embodiment shown in FIG. 4 uses on-die PN junctions 310 312 314 to provide 320 322 an indication of die temperature to controller 200. The forward voltage drop of a PN junction varies with the junction temperature. While three PN junctions 310 312 314 are shown, a single junction may be used. Sense junctions 310 312 314 may be placed in different areas of die 100 and may be brought out to separate bonding pads, or wired in series as shown. By monitoring the temperature dependent characteristics of PN junctions 310 312 314, controller 200 can adjust 170 the current flowing through load 160 and 165 to maintain die 100 at a predetermined temperature. Other temperature sensing may also be used, such as applying a constant voltage across one or more PN junctions and measuring the current, which will be an exponential function of temperature. Temperature-dependent resistors may also be used. Multiple heat generating load resistors 160 may be used to heat the die, or semiconductor devices such as transistor 165 may be used to generate heat. Single or multiple heat generating loads may be placed on die 100.

While the embodiments of the present invention have been illustrated in detail, it should be apparent that modifications and adaptations to these embodiments may occur to one skilled in the art without departing from the scope of the present invention as set forth in the following claims.

1. A system for temperature stabilizing an integrated circuit comprising:
an integrated circuit die having one or more power supply connections and one or more power return connections, the die containing one or more heat generating loads,
a sensor sensing operating characteristics of the die, and
a controller connected to the sensor for controlling current flowing through the heat generating loads to stabilize the operating temperature of the die.

2. The system of claim 1 where the heat generating load is a resistor.

3. The system of claim 1 where the heat generating load is a transistor.

4. The system of claim 1 where the heat generating load is a resistor in series with a transistor.

5. The system of claim 1 where the controller is substantially integrated on to the integrated circuit die.

6. The system of claim 1 where the sensor comprises a current sensor sensing current flowing through the power connections to the die.

7. The system of claim 6 where the current sensor is a resistor.

8. The system of claim 7 where the current sensing resistor is integrated onto the die.

9. The system of claim 6 where the controller varies the current to the heat generating loads to maintain a constant amount of current flowing through the current sensor.

10. The system of claim 7 where the controller varies the current to the heat generating loads to maintain a constant voltage drop across the current sensing resistor.

11. The system of claim 1 where the sensor is one or more semiconductor junctions on the die sensing die temperature.

12. The system of claim 11 where the controller varies the current to the heat generating loads to maintain a constant die temperature as sensed by the semiconductor junctions.

13. A method of stabilizing the temperature of an integrated circuit die containing one or more current-controlled heat generating loads on the die comprising:
sensing an operating characteristic of the die, and
controlling the current through the loads to hold the sensed operating characteristic constant.

14. The method of claim 13 where the operating characteristic sensed is the current consumption of the die including the current consumption of the loads.

15. The method of claim 13 where the operating characteristic sensed is the temperature of the die.

16. The method of claim 14 where the temperature of the die is sensed using one or more PN junctions.

17. The method of claim 14 where the temperature of the die is sensed using a temperature dependent resistor.
